(19) United States
(12) Patent Application Publication
(10) Pub. No.: US 2023/0369550 A1
(43) Pub. Date: Nov. 16, 2023

(54) METHOD FOR PRODUCING OPTOELECTRONIC SEMICONDUCTOR COMPONENTS, AND OPTOELECTRONIC SEMICONDUCTOR COMPONENT, AND AN OPTOELECTRONIC ARRANGEMENT

(71) Applicant: ams-OSRAM International GmbH, Regensburg (DE)

(72) Inventors: Norwin VON MALM, Nittendorf (DE); Laura KREINER, Regensburg (DE); Matthias GOLDBACH, Pentling (DE)

(21) Appl. No.: 18/028,169

(22) PCT Filed: Sep. 15, 2021
(86) PCT No.: PCT/EP2021/075296

§ 371 Date: Mar. 23, 2023

(30) Foreign Application Priority Data
Sep. 24, 2020 (DE) 10 2020 124 921.7

(51) Int. Cl. H01L 33/58; H01L 25/075; H01L 33/62

(52) U.S. Cl. CPC H01L 33/58; H01L 25/0753; H01L 33/62; H01L 2933/0058; H01L 2933/0066

(57) ABSTRACT

The invention relates to a method for producing a plurality of optoelectronic semiconductor components, comprising the steps: a) providing a carrier composite having a plurality of component regions; b) forming a filter layer on the carrier composite; c) forming a radiation conversion layer on the filter layer; d) arranging a plurality of semiconductor bodies on the radiation conversion layer, wherein the semiconductor bodies each have a semiconductor layer sequence having an active region provided for radiation generation and are free of a substrate stabilizing the semiconductor body; e) forming a contact layer for producing an electrical connection between the semiconductor bodies; f) forming an insulation layer on the contact layer; g) forming electrical contact surfaces, each of which are electrically conductively connected to the contact layer; and h) separating the carrier composite into the optoelectronic semiconductor components.--

The present invention relates to a method for producing optoelectronic semiconductor components and to an optoelectronic semiconductor component, as well as to an optoelectronic arrangement.

For various requirements, for example coupling into waveguides for the backlighting of displays, components which are distinguished by a particularly compact design are required. Conventional designs in which the light-emitting diodes, abbreviated to LEDs, are located in a cavity of a housing can no longer readily be miniaturized further, since the materials used for the housing reach the limits of mechanical stability and reflectance with the small wall thicknesses then required.

It is an object to achieve reliable radiation input coupling even for particularly thin waveguides. This object is achieved by a method for producing optoelectronic semiconductor components, or an optoelectronic semiconductor component, according to the independent patent claims. The other patent claims relate to further configurations and expediencies.

A method for producing a multiplicity of optoelectronic semiconductor components is provided.

According to at least one embodiment of the method, the method comprises a step in which a carrier assembly having a multiplicity of component regions is provided.

The carrier is, in particular, transmissive for the radiation to be generated by the optoelectronic semiconductor component. The radiation to be generated lies particularly in the visible spectral range. For example, the carrier contains glass, quartz, sapphire, a glass ceramic, a ceramic or a polymer material. Expediently, the material of the carrier assembly is insensitive to the radiation to be generated, in particular to the shortwave fraction of the radiation to be generated, for example blue radiation, and to the temperature occurring due to heat losses during operation of the semiconductor component to be produced. Preferably, the carrier assembly is free of optical scattering centers. This means that at least the majority, for example at least 60%, of the radiation passing through the carrier during operation emerges from the carrier without being scattered inside the carrier.

Preferably, the carrier assembly is provided in a form which is unstructured in the lateral direction, so that the carrier assembly is divided in particular during a final singulation step of the production method, and a carrier for each optoelectronic semiconductor component produced is thereby respectively obtained from the carrier assembly. The side faces of the individual carriers of an optoelectronic semiconductor component are thus formed during the singulation. In contrast thereto, the carrier assembly may also already be provided in the form of individual carriers, the individual carriers being held together for example by means of an auxiliary carrier. The subsequent singulation may then, for example, be carried out by removing the auxiliary carrier.

A thickness of the carrier assembly is for example between 20 µm inclusive and 1000 µm inclusive, preferably between 50 µm inclusive and 120 µm inclusive. The carrier assembly may be mechanically rigid, for example in the form of a wafer or a plate, or flexible, for example in the form of a film.

According to at least one embodiment of the method, the method comprises a step in which a filter layer is formed on the carrier assembly. The filter layer is in particular formed, in particular deposited, surface-wide on the carrier assembly.

For example, the filter layer has a multiplicity of dielectric layers, successive layers differing in refractive index. In particular, the filter layer may have an angle filter from which only radiation fractions which impinge at a relatively small angle with respect to the normal of the carrier are transmitted and radiation fractions beyond a limit angle, for example an angle of at most 30°, at most 20° or at most 10°, with respect to the surface normal of the carrier are reflected. In this way, radiation fractions which would not be coupled into a light guide anyway during coupling into the latter may be reflected at the filter layer and at least partly converted into radiation fractions having an angle less than the limit angle, for example by absorption processes and renewed recombination processes, also referred to as photon recycling, and/or by scattering. The fraction of the radiation usable for the coupling into a light guide in relation to the radiation emitted overall by the optoelectronic semiconductor component is thus increased.

As an alternative or in addition to an angle filter, the filter layer may have a polarizer. For example, the polarizer has a ruled grating consisting of a reflective metal, for example silver. Silver is distinguished by a high reflectivity in the visible spectral range. Another metal may, however, also be used. The filter layer may have further layers, for example a protective layer, for instance an oxide layer, in which a metal layer of the polarizer is embedded.

By means of the polarizer, it is possible to achieve the effect that radiation emerging from the optoelectronic semiconductor component is polarized or at least partially polarized. Radiation fractions having the polarization not to be transmitted may be reflected back at the polarizer and subsequently at least partially redistributed in the desired polarization direction, for example by photon recycling and/or scattering.

According to at least one embodiment of the method, the method comprises a step in which a radiation conversion layer is formed on the carrier assembly, in particular on the filter layer. The radiation conversion layer may comprise one or more inorganic or organic phosphors or radiation converters based on semiconductor material, for example quantum dots. The radiation conversion layer is preferably formed in a structured manner on the filter layer, in which case the structuring may be carried out retrospectively, for example by lithography and etching, or directly during the coating, for example by using a previously applied resist mask which covers regions not to be coated.

According to at least one embodiment of the method, a multiplicity of semiconductor bodies are arranged on the carrier assembly, in particular on the radiation conversion layer. In particular, the semiconductor bodies respectively have a semiconductor layer sequence with an active region intended for the generation of radiation. Preferably, the semiconductor bodies are free of a substrate stabilizing the semiconductor body. For example, the semiconductor bodies have a thickness of between 0.1 µm inclusive and 10 µm inclusive, preferably between 0.2 µm inclusive and 6 µm inclusive, particularly preferably between 0.4 µm inclusive and 1 µm inclusive. A lateral extent of the semiconductor bodies is, for example, between 5 µm inclusive and 1000 µm inclusive, preferably between 20 µm inclusive and 100 µm inclusive.

According to at least one embodiment of the method, the method comprises a step in which a contact layer for establishing an electrical connection between the semiconductor bodies is formed. Preferably, the formation of the contact layer is carried out after having arranged the semiconductor bodies on the radiation conversion layer. The contact layer is, in particular, configured in the form of planar contacting.

The contact layer is preferably deposited on the semiconductor bodies, the contact layer being routed over the side faces of the semiconductor bodies and running locally between neighboring semiconductor bodies on the radiation conversion layer. Semiconductor bodies without a substrate are particularly suitable for the formation of the contact layer, since the small overall height achievable in this way simplifies the formation of a continuous contact path along the side face as far as the radiation conversion layer.

In contrast thereto, at least some semiconductor bodies or all semiconductor bodies which are arranged on a component region may already be electrically connected to one another before the semiconductor bodies are arranged on the radiation conversion layer.

According to at least one embodiment of the method, the method comprises a step in which an insulation layer is formed on the contact layer. Expediently, the insulation layer is formed in such a way that it has openings in which the contact layer is exposed.

According to at least one embodiment of the method, the method comprises a step in which electrical contact pads are formed, the contact pads respectively being electrically conductively connected to the contact layer. In particular, at least two electrical contact pads, for example precisely two electrical contact pads, are formed in each component region. Expediently, the electrical contact pads are electrically conductively connected to the contact layer in the openings of the insulation layer. In particular, the electrical contact pads and the contact layer may be directly adjacent to one another in the openings.

According to at least one embodiment of the method, the method comprises a step in which the carrier assembly is singulated into the optoelectronic semiconductor components. The singulated optoelectronic semiconductor components in particular respectively have a carrier as part of the carrier assembly, a multiplicity of semiconductor bodies on the carrier and at least two electrical contact pads for the external electrical contacting. The electrical contact pads are, in particular, located on a side of the optoelectronic semiconductor component lying opposite the radiation exit face. The radiation exit face is in particular a face through which at least 60%, preferably at least 80%, of the radiation emitted overall emerges from the optoelectronic semiconductor component.

The singulation of the carrier assembly may for example be carried out by scoring and fracturing, laser cutting, stealth dicing or sawing.

In at least one embodiment of the method for producing a multiplicity of optoelectronic semiconductor components, a carrier assembly having a multiplicity of component regions is provided. A filter layer is formed on the carrier assembly, and a radiation conversion layer is formed on the filter layer. A multiplicity of semiconductor bodies are arranged on the radiation conversion layer, the semiconductor bodies respectively having a semiconductor layer sequence with an active region intended for the generation of radiation and being free of a substrate stabilizing the semiconductor body. A contact layer for establishing an electrical connection between the semiconductor bodies is formed. An insulation layer is formed on the contact layer. Electrical contact pads, which respectively are electrically conductively connected to the contact layer, are formed. The carrier assembly is singulated into the optoelectronic semiconductor components, the singulated optoelectronic semiconductor components respectively having a carrier as part of the carrier assembly, a multiplicity of semiconductor bodies and at least two electrical contact pads for the external electrical contacting.

In particular, the filter layer has a polarization filter and/or an angle filter, the angle filter transmitting the radiation fractions which travel perpendicularly with respect to the radiation exit face and predominantly reflecting radiation fractions which impinge at an angle which is greater than a limit angle.

The production steps are preferably carried out in the order listed. This is not, however, absolutely necessary. For example, the electrical connection between the semiconductor bodies may also at least partly be carried out already before the semiconductor bodies are arranged on the radiation conversion layer.

According to at least one embodiment of the method, during the arranging of the semiconductor bodies on the radiation conversion layer, a plurality of semiconductor bodies are transferred simultaneously onto the carrier assembly. For example, at least 80% or even all semiconductor bodies for an optoelectronic semiconductor component to be produced are transferred simultaneously onto the carrier assembly.

According to at least one embodiment of the method, the semiconductor bodies are transferred from a temporary substrate, a center spacing between neighboring semiconductor bodies remaining the same during the transfer. In particular, the center spacing in the completed optoelectronic semiconductor component corresponds to the center spacing of the semiconductor bodies with which the semiconductor bodies were deposited on their original growth substrate.

The distances between neighboring semiconductor bodies in the finished optoelectronic semiconductor component may thus already be set during lithographic structuring of the semiconductor layer sequence for the semiconductor bodies.

According to at least one embodiment of the method, the semiconductor bodies on the temporary substrate are tested and only semiconductor bodies functioning according to specification are arranged on the radiation conversion layer. For example, the semiconductor bodies are tested in respect of an electronic or optoelectronic property, for example in respect of the peak wavelength of the emission or a characteristic parameter of a current-voltage characteristic.

Free spaces thereby created on the radiation conversion layer may subsequently be filled, so that there are only semiconductor bodies functioning according to specification on the radiation conversion layer.

According to at least one embodiment of the method, the semiconductor bodies on the temporary substrate are free of a growth substrate for epitaxial deposition of the semiconductor layer sequence. During the transfer onto the radiation conversion material, the growth substrate of the semiconductor bodies is thus already no longer present. For example, the growth substrate is removed after the semiconductor bodies have been fastened on the temporary carrier.

Alternatively, the temporary carrier itself may also be the growth substrate. In this case, the transfer may be carried out directly from the growth substrate onto the carrier assembly. For example, semiconductor bodies to be transferred may be selectively detached from the growth substrate, for example by a laser lift-off (LLO) method.

According to at least one embodiment of the method, the radiation conversion layer is configured to be structured in such a way that a separate radiation conversion element of the radiation conversion layer is assigned to each component region and the radiation conversion layer is not divided during the singulation. It is thus possible to avoid the risk that the radiation conversion layer will be damaged during the singulation. Furthermore, the singulation method may be selected independently of the properties of the radiation conversion layer.

According to at least one embodiment of the method, the filter layer is divided during the singulation. The filter layer and the carrier of the optoelectronic semiconductor component produced therefore end flush on the side face of the optoelectronic semiconductor component.

An optoelectronic semiconductor component is furthermore provided.

The method described above is particularly suitable for producing the optoelectronic semiconductor component. Features described in connection with the method may therefore also be used for the optoelectronic semiconductor component, and vice versa.

In at least one embodiment of the optoelectronic semiconductor component, the optoelectronic semiconductor component has a carrier, which forms a radiation exit face of the optoelectronic semiconductor component. The optoelectronic semiconductor component furthermore comprises a multiplicity of semiconductor bodies which are arranged on the carrier, the semiconductor bodies respectively having a semiconductor layer sequence with an active region intended for the generation of radiation and in particular being free of a substrate stabilizing the semiconductor body. The optoelectronic semiconductor component furthermore comprises a filter layer between the carrier and the semiconductor bodies, and a radiation conversion layer between the carrier and the semiconductor bodies, the radiation conversion layer in particular extending continuously over the semiconductor body. The optoelectronic semiconductor component furthermore comprises a contact layer for establishing an electrical connection between the semiconductor bodies, and an insulation layer on a side of the contact layer facing away from the carrier. At least two electrical contact pads for the external electrical contacting are arranged on the insulation layer and are electrically conductively connected to the contact layer.

According to at least one embodiment of the optoelectronic semiconductor component, the filter layer covers the carrier surface-wide. The radiation generated in the semiconductor bodies during operation thus has to pass through the filter layer before it can emerge from the radiation exit face.

According to at least one embodiment of the optoelectronic semiconductor component, the radiation conversion layer protrudes beyond the radiation conversion layer in a lateral direction.

In particular, the radiation conversion layer may be separated from the side faces of the carrier along the entire perimeter of the optoelectronic semiconductor component.

According to at least one embodiment of the optoelectronic semiconductor component, neighboring semiconductor bodies are arranged at a distance of between 1 µm inclusive and 10 µm inclusive from one another. By such small distances, which cannot readily be achieved with conventional pick-and-place placement methods, particularly uniform illumination and a high luminance may be achieved even with relatively small semiconductor bodies.

According to at least one embodiment of the optoelectronic semiconductor component, the filter layer has a polarization filter and/or an angle filter. In particular, the angle filter lets through radiation fractions which travel perpendicularly with respect to the radiation exit face and, predominantly, for example to an extent of at least 70% or at least 80%, reflects radiation fractions which impinge on the carrier at an angle which is greater than a limit angle.

According to at least one embodiment of the optoelectronic semiconductor component, the electrical contact pads together cover at least 60% of a base face of the optoelectronic semiconductor component. Via the relatively large electrical contact pads, heat losses occurring during operation of the optoelectronic semiconductor component may be dissipated efficiently.

According to at least one embodiment of the optoelectronic semiconductor component, the semiconductor bodies are arranged in the form of a matrix. For example, the semiconductor bodies are at least in part interconnected in series and/or parallel by means of the contact layer. For example, the semiconductor bodies of a row are respectively connected electrically in series by means of the contact layer.

According to at least one embodiment of the optoelectronic semiconductor component, the rows are interconnected in parallel with one another, in particular by means of the electrical contact pads. In particular, all semiconductor bodies of the optoelectronic semiconductor component may be contacted together by means of precisely two external electrical contact pads.

Furthermore, an optoelectronic arrangement having at least one electronic semiconductor component as described above is provided. The optoelectronic arrangement has, for example, a connection carrier on which the optoelectronic semiconductor component is fastened. For example, the connection carrier is a circuit board.

The optoelectronic arrangement is, for example, a backlighting unit for a display apparatus or part of a backlighting unit for a display apparatus. In particular, the optoelectronic arrangement is adapted to couple radiation coupled out from the radiation exit face of the optoelectronic semiconductor component during operation of the optoelectronic arrangement into a side face of a light guide, in particular a flat light guide.

According to at least one embodiment of the optoelectronic arrangement, the radiation exit face of the carrier runs parallel or substantially parallel with respect to a main extent plane of the connection carrier. The main extent plane in this case runs, for example, parallel or substantially parallel to the side face of the flat light guide into which the radiation is intended to be coupled.

According to at least one embodiment of the optoelectronic arrangement, the radiation exit face runs perpendicularly or substantially perpendicularly with respect to a main extent plane of the connection carrier. In this case, the main extent plane of the connection carrier may run perpendicularly or substantially perpendicularly with respect to the side face of the flat light guide.

The terms “substantially perpendicularly” and “substantially parallel” in this context respectively mean, in particular, a deviation by at most 10°.

According to at least one embodiment of the optoelectronic arrangement, a side face of the carrier, running obliquely or perpendicularly with respect to the radiation exit face, bears on the connection carrier. Mounting of the optoelectronic semiconductor component on the connection carrier, in such a way that the radiation exit face of the carrier runs perpendicularly with respect to the main extent plane of the connection carrier, is thereby simplified.

With the method, or respectively the optoelectronic semiconductor component, the following effects may in particular be achieved.

By the described method, optoelectronic semiconductor components which are distinguished by a particularly small size may be produced. Coupling into very thin waveguides, in particular having a thickness of less than 1 mm, for example 500 µm or 700 µm, is thereby simplified.

High luminances may be achieved since the individual semiconductor bodies can be placed at a very small, lithographically definable distance from one another. The individual semiconductor bodies themselves may be relatively small and thus produced with a high yield. In particular, even with small extents of the optoelectronic semiconductor component, the semiconductor bodies may be arranged in the form of a matrix in two or more rows, respectively having a plurality of semiconductor components.

It has furthermore been found that the method may be carried out particularly economically so that the overall costs for an optoelectronic semiconductor component to be produced are low. The transfer of the individual semiconductor bodies onto the final carrier of the optoelectronic semiconductor component may, for example, be performed by means of a stamp and may therefore be carried out particularly flexibly. In particular, the method may easily be matched to different sizes of the carrier and/or of the semiconductor bodies to be used.

By means of the filter layer, the emission may be matched in respect of the angle range and/or the polarization to the respective use, in particular to the downstream flat light guide. Radiation fractions which could not be coupled into the flat light guide anyway, or which are not usable because of their polarization, may be reflected by the filter layer back into the optoelectronic semiconductor components and converted there at least partially into usable radiation fractions, for example by recycling processes. The efficiency of the overall system for the backlighting of a display apparatus thereby increases significantly.

Further configurations and expediencies may be found in the following description of the exemplary embodiments in conjunction with the figures, in which:

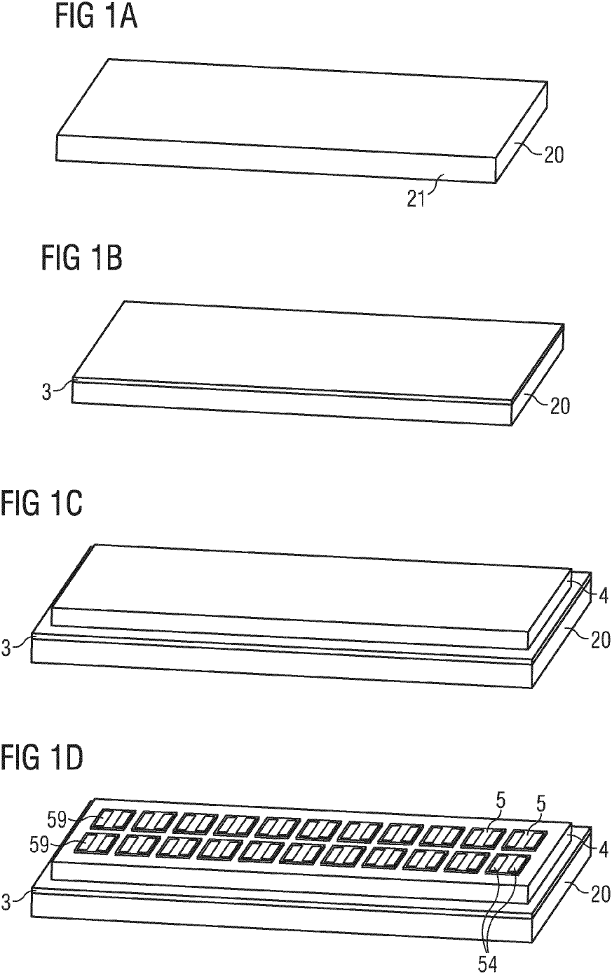

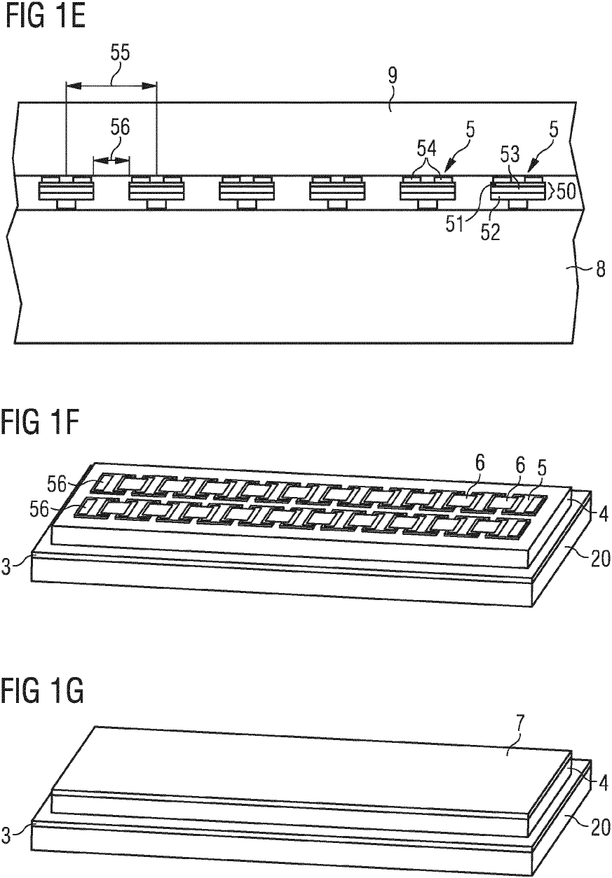

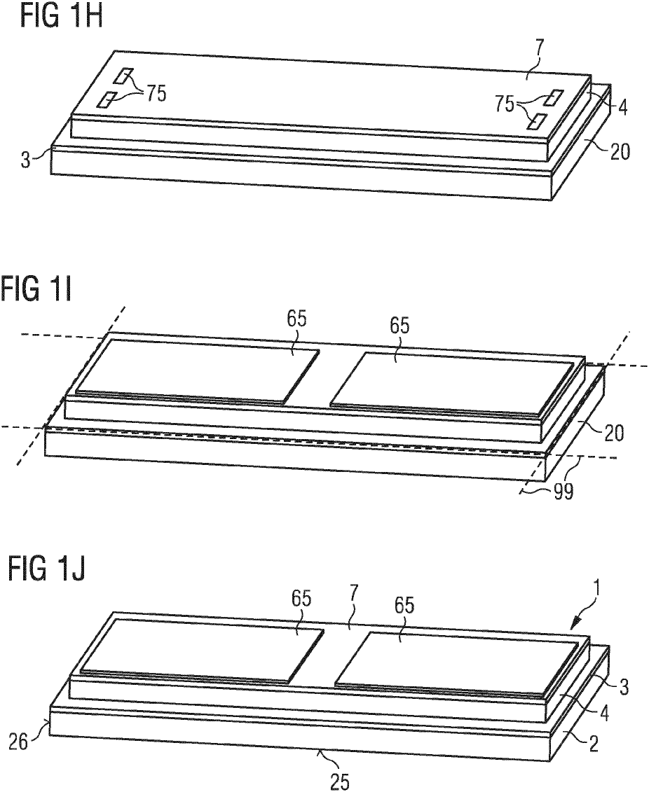

FIGS. 1A to 1J show an exemplary embodiment of a method for producing optoelectronic semiconductor components, FIGS. 1A, 1B, 1C, 1D, 1F, 1G, 1H, 1I and 1J respectively representing a perspective representation of an intermediate step and FIG. 1E representing an intermediate step with a schematic sectional view of a temporary substrate;

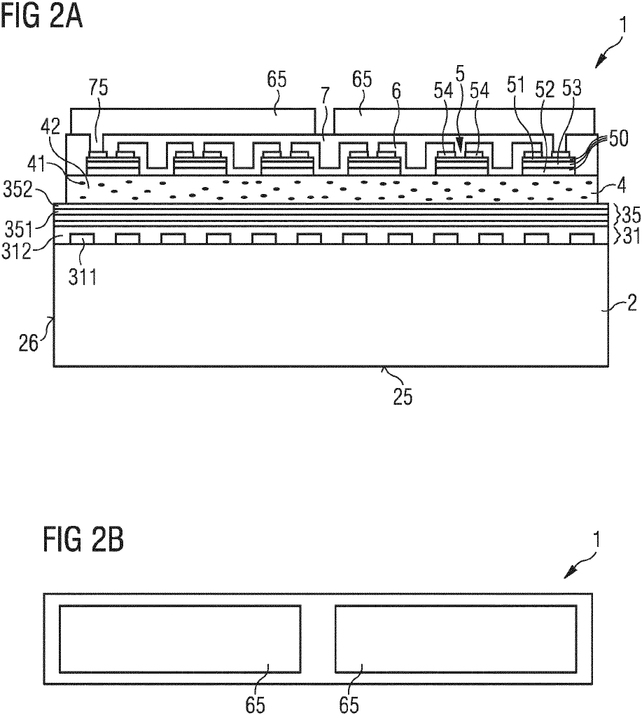

FIGS. 2A and 2B show an exemplary embodiment of an optoelectronic semiconductor component in a rear view (FIG. 2B) and in an associated schematic side view (FIG. 2A); and

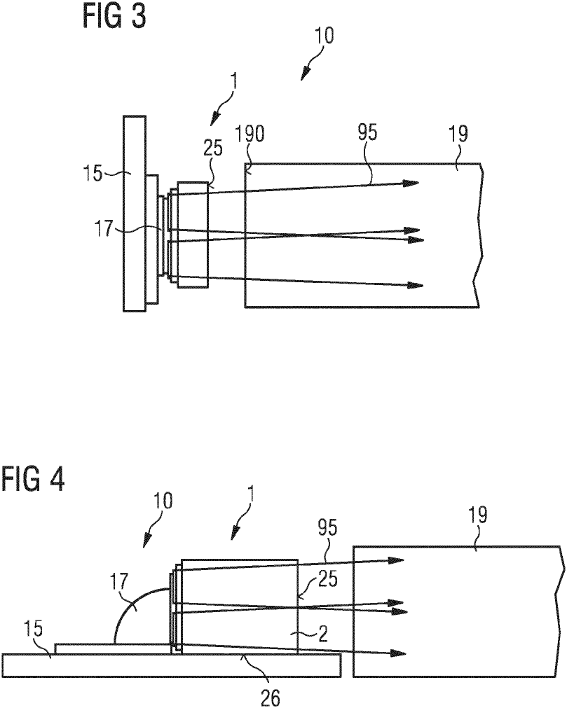

FIGS. 3 and 4 respectively show an exemplary embodiment of an optoelectronic arrangement in a schematic side view.

The figures are in each case schematic representations and are therefore not necessarily true to scale. Rather, individual elements, and in particular layer thicknesses, may be represented exaggeratedly large for improved representation and/or improved understanding.

Elements which are the same or of the same type, or which have the same effect, are provided with the same references in the figures.

FIGS. 1A to 1I represent a method for producing optoelectronic semiconductor components according to one exemplary embodiment, only one subregion of a carrier assembly 20 with a component region 21, from which an optoelectronic semiconductor component is obtained during the production, being shown for simplified representation. Of course, a multiplicity of optoelectronic semiconductor components, which may in particular be formed as a matrix respectively on a component region 21, may be produced simultaneously with the method.

As represented in FIG. 1A, a carrier assembly 20 having a multiplicity of component regions 21 is provided. The carrier assembly 20 may, in particular, be an element which is entirely unstructured in the lateral direction. The carrier assembly 20 may be mechanically rigid or flexible.

A filter layer 3 is formed on the carrier assembly 20 (FIG. 1B). The filter layer 3 is, in particular, applied surface-wide on the carrier assembly 20 and not structured. The filter layer 3 may in particular be configured with a plurality of layers, in which case the individual layers may for example be produced by vapor deposition or sputtering. Details of the filter layer 3 will be explained in more depth in connection with FIG. 2A.

A radiation conversion layer 4 is formed on the carrier assembly 20 with the filter layer 3 (FIG. 1C). Preferably, the radiation conversion layer 4 is formed in a structured manner, so that the radiation conversion layer 4 does not cover the filter layer 3 fully. In particular, the edges of the respective component region 21 are free of material of the radiation conversion layer 4, so that the radiation conversion layer 4 does not need to be divided during the subsequent singulation. The radiation conversion layer 4 may be applied in a form which is already structured, or may be applied surface-wide and subsequently structured, for example by a lithography step and a subsequent etching step. All semiconductor bodies 5 of a component are covered by a continuous part of the radiation conversion layer 4.

The radiation conversion layer 4 may comprise one or more inorganic or organic or nanoscale phosphors 41, for example quantum dots based on a III-V compound semiconductor material or a II-VI compound semiconductor material (cf. FIG. 2A). For example, a KSF phosphor or a β-SiAlON phosphor are suitable as phosphors. The phosphors 41 may be embedded in a matrix material 42, in particular a transparent matrix material. For example, the matrix material contains or consists of a polymer material, for example a crosslinked polysiloxane. For the deposition of the radiation conversion layer 4, the phosphors may be mixed into the matrix material and then laid on by means of a coating process, and optionally cured thermally or optically. Spraying, blade coating, dip coating or spin coating in one or more passes are for example suitable for the application. Alternatively, a process such as a sol-gel transition may also be employed. Alternatively, the phosphors may also initially be applied without a matrix material, for instance in the form of a solution or suspension in a solvent or as a powder, and subsequently fixed on the carrier assembly 20 by applying a matrix material 42. If necessary, a planarization layer may subsequently be formed on the side facing away from the carrier assembly 20. For simplified representation, this is not explicitly shown in the figures.

Subsequently, as represented in FIG. 1D, a multiplicity of semiconductor bodies 5 are transferred onto the carrier assembly 20. For example, the semiconductor bodies 5 are fastened on the radiation conversion layer 4 by a connecting layer, for instance a transparent adhesive layer.

For example, as schematically represented in FIG. 1E, the semiconductor bodies 5 may be transferred from a temporary substrate 8, for example by means of a stamp 9 from the temporary substrate 8 onto the carrier assembly 20. Preferably, a plurality of semiconductor bodies 5, in particular all semiconductor bodies 5 for an optoelectronic semiconductor component to be produced, are transferred simultaneously from the temporary substrate 8 onto the carrier assembly 20. A center spacing 55 between neighboring semiconductor bodies 5 on the temporary substrate 8 remains unchanged during this transfer process, so that the semiconductor bodies 5 are located on the carrier assembly 20 with the original center spacing after the transfer process. At least for all semiconductor bodies 5 which are transferred in the same step, the center spacings from their neighbors thus do not change.

Semiconductor bodies 5 for a plurality of component regions 21, or for all component regions 21 of the carrier assembly 20, may also be transferred simultaneously.

Before the transfer onto the carrier assembly 20, the semiconductor bodies 5 may be tested on the temporary substrate 8 so that only semiconductor bodies 5 which comply with the predetermined requirements, for instance in respect of the brightness or emission wavelength, are applied on the carrier assembly 20. In particular, the transfer may be carried out in such a way that semiconductor bodies 5 not complying with the requirements are not transferred from the temporary substrate. Free spaces thereby created on the carrier assembly 20 may subsequently be filled with semiconductor bodies 5 capable of functioning according to specification. The reject rate during the production of optoelectronic semiconductor components 1 may thereby be reduced significantly. As represented in FIG. 1F, the semiconductor bodies 5 are electrically connected to one another by means of a contact layer 6. In the exemplary embodiment shown, the semiconductor bodies 5 are arranged in the form of a matrix in two rows 56, the semiconductor bodies 5 of a row 56 respectively being electrically connected in series. It is, however, also possible to produce different forms of interconnection, for example parallel interconnection or series-parallel interconnection.

Subsequently, as represented in FIG. 1G, an insulation layer 7 which fully covers the semiconductor bodies 5 of a component region 21 is applied. Openings 75, in which the contact layer 6 is exposed, are formed in the insulation layer 7 (FIG. 1H).

Subsequently, as represented in FIG. 1I, contact pads 65 for the external electrical contacting of the optoelectronic semiconductor components to be produced are formed on the insulation layer 7, the contact pads 65 respectively being connected electrically conductively to the contact layer 6 in the openings 5.

A single-layer or multilayer construction is suitable for the contact layer 6 and the contact pads 65. For example, at least one layer comprises or consists of a metal, for example copper, titanium, platinum, nickel, silver, gold. The contact layer and/or the contact pad 65 may furthermore contain a transparent conductive oxide (TCO) material, for example indium tin oxide (ITO) or zinc oxide (ZnO), or a plurality of such layers. In particular, the contact layer 6 and/or the contact pads 65 may be configured to be reflective on the side facing toward the semiconductor bodies 5 for the radiation to be generated in the semiconductor bodies 5.

Finally, the carrier assembly 20 is singulated so that each optoelectronic semiconductor component 1 produced respectively has a carrier 2 as part of the carrier assembly 20 with semiconductor bodies 5 arranged thereon and at least two contact pads 65 for the external electrical contacting of the semiconductor bodies 5.

The singulation is carried out along the singulation lines 99 represented in FIG. 1I. The singulation may for example be carried out by scoring and fracturing, laser cutting, stealth dicing or sawing. During the singulation, preferably only the carrier assembly 20 and the filter layer 3 arranged thereon are divided.

The completed optoelectronic semiconductor component 1 is represented in FIG. 1J. The side faces of the carriers 2 formed from the carrier assembly 20 during the singulation may have traces characteristic of the singulation method, for example sawing traces or traces of chemical material erosion and/or material erosion by coherent radiation.

In the exemplary embodiment shown, the optoelectronic semiconductor component 1 has, for example, a lateral extent of 700 pm x 400 pm. A thickness of the carrier 2 is, for example, between 50 pm inclusive and 120 pm inclusive. Depending on the use of the optoelectronic semiconductor component 1, however, these dimensions may be varied within wide limits. An exemplary embodiment of an optoelectronic semiconductor component 1 is represented in FIGS. 2A and 2B.

The optoelectronic semiconductor component 1 has a carrier 2, which forms a radiation exit face 25 of the optoelectronic semiconductor component 1. A multiplicity of semiconductor bodies 5 are arranged on the carrier, the semiconductor bodies respectively having a semiconductor layer sequence 50 with an active region 53 intended for the generation of radiation.

The active region 53 is located between a first semiconductor layer 51 of a first conduction type and a second semiconductor layer 52 of a second conduction type, which is different to the first conduction type. For example, the first semiconductor layer 51 is n-conductive and the second semiconductor layer 52 is p-conductive, or vice versa. The first semiconductor layer 51 and the second semiconductor layer 52 are respectively connected electrically conductively to a connection face 54 so that, by applying an electrical voltage between the two connecting faces, charge carriers can be injected from opposite sides into the active region and recombine there by emitting radiation.

The semiconductor bodies 5 per se are respectively free of a substrate stabilizing the semiconductor bodies and are therefore particularly thin, for example with a thickness of between 0.4 µm and 10 µm, for example about 5 µm. The mechanical stabilization of the semiconductor bodies 5 is carried out by means of the common carrier 2.

The connection faces 54 are respectively arranged on the side of the semiconductor bodies 5 facing away from the carrier 2. For example, the connection faces 54 are located at a distance of at most 10 pm or at most 5 µm from the radiation conversion layer 4. The connection faces 54 of neighboring semiconductor bodies 5 are electrically connected to one another by means of a contact layer 6, for example in a series interconnection. The contact layer 6 is routed over the side faces of the semiconductor bodies 5 and runs between the semiconductor bodies on the radiation conversion layer 4, in particular directly on the radiation conversion layer 4.

An insulation layer 7 is arranged on a side of the contact layer 6 facing away from the carrier 2. The insulation layer 7 has openings 75 in which, for external electrical contacting, the contact pads 65 of the optoelectronic semiconductor component 1 are electrically conductively connected to the contact layer 6.

As represented in FIG. 2B, the electrical contact pads 65 together cover a majority, in particular at least 60% or at least 80%, of a base face of the optoelectronic semiconductor component 1. Via the relatively large electrical contact pads, heat losses occurring during operation may be dissipated efficiently from the optoelectronic semiconductor component 1. Furthermore, the contact pads may reflect radiation impinging on them back in the direction of the radiation exit face 25.

A radiation conversion layer 4 and a filter layer 3 are arranged between the semiconductor bodies 5 and the carrier 2.

The radiation conversion layer 4 is adapted to convert a primary radiation generated in the semiconductor bodies 5, for example radiation in the blue spectral range or in the ultraviolet spectral range, into radiation with a longer wavelength, for example into radiation fractions in the green and red spectral ranges or into radiation fractions in the blue, green and red spectral ranges, for primary radiation in the ultraviolet spectral range. The phosphors 41 of the radiation conversion layer 4 are, for example, embedded in the matrix material 42.

In the exemplary embodiment shown, the filter layer 3 has a polarization filter 31 and an angle filter 35. The filter layer may also, however, have only a polarization filter or only an angle filter. The polarization filter 31 is for example formed by a metal layer 311 structured in the form of strips, a protective layer 312 which protects the metal layer 311, for example from oxidation, optionally being provided in addition. The protective layer 212 comprises, for example, a chemically inert material which preferably has a low absorption in the entire emission spectrum of the optoelectronic semiconductor component or consists of such a material. For example, an oxide, for instance silicon oxide, is suitable.

The metal layer 311 expediently comprises a metal with a high reflectivity for the radiation to be generated in the active region of the semiconductor bodies 5. For example, silver is distinguished by a high reflectivity in the visible spectral range.

The angle filter 35 is formed by a sequence of a plurality of first dielectric layers 351 and second dielectric layers 352, the first layers 351 and the second layers 352 preferably being distinguished by a refractive index difference which is as low as possible. By suitable selection of the layer thicknesses and materials of the layers, the angle filter may be formed in such a way that it is transmissive only for a relatively small angle range about a normal to the radiation exit face 25. For example, the angle filter is configured to be reflective for the radiation beyond a limit angle of 30°, 20° or 10°. Only radiation from a relatively small angle range about the normal is thus coupled into the carrier 2. It is thus possible to achieve the effect that only a very small fraction of the radiation emerges from the side faces 26 of the carrier 2 and the overall efficiency of the system is therefore increased.

The filter layer 3 protrudes beyond the radiation conversion layer 4 in the lateral direction, in particular along the entire perimeter. By means of the filter layer 3, it is reliably possible to achieve the effect that, of the primary radiation as well as of the secondary radiation generated in the radiation conversion layer, the radiation fractions coupled into the carrier 2 are only or at least predominantly those which are usable when coupling radiation out from the radiation exit face 25 for the use of the optoelectronic semiconductor component 1, for example in respect of the polarization and/or exit angle of the emerging radiation. Of the exemplary embodiment described, the lateral extent of the optoelectronic semiconductor component along the vertical direction may also be constant or substantially constant. For example, the filter layer 3 and the radiation conversion layer 4 may also have the same extent in the lateral direction. In particular, the lateral extent may also be equal to the lateral extent of the carrier and therefore of the optoelectronic semiconductor component 1. The semiconductor component 1 is in this case free or substantially free of steps.

Furthermore, the elements which have a smaller lateral extent than the carrier in FIG. 2A, for example the radiation conversion layer 4 and/or the semiconductor bodies 5 and/or the contact layer 6 and/or the contact pads 65, may be surrounded by a reflective layer. A polymer material, for instance a silicone, which is filled with particles, for instance with Al₂O₃ particles, is for example suitable for the reflective layer.

FIG. 3 represents an exemplary embodiment of an optoelectronic arrangement 10. The optoelectronic arrangement 10 has an optoelectronic semiconductor component 1 which is configured as described in connection with FIGS. 2A and 2B.

The optoelectronic semiconductor component 1 is arranged on a connection carrier 15 and is connected thereto by means of a connecting means 17, for example a solder or an adhesive, in particular an electrically conductive adhesive. A main extent plane of the connection carrier 15 runs parallel to a side face 190 of a flat light guide 19, into which the radiation emitted by the optoelectronic arrangement 10 is intended to be coupled. As schematically represented by the arrows 95, the optoelectronic semiconductor bodies 5 emit highly directionally so that the emitted radiation can be coupled efficiently into the flat light guide 19 through the side face 190. In this way, a particularly high efficiency of the overall system may be achieved. Preferably, the emission spectrum of the optoelectronic semiconductor component 1 is matched to the transmission spectra of the color filters for the display apparatus to be backlit. For this purpose, in particular, phosphors having a narrow emission spectrum, for example quantum dots, are suitable for the radiation conversion layer 4. In principle, however, it is also possible to use other phosphors.

The exemplary embodiment of an optoelectronic arrangement 10 as represented in FIG. 4 corresponds substantially to the exemplary embodiment described in connection with FIG. 3. In contrast thereto, a main extent plane of the connection carrier 15 runs parallel to a main extent plane of the flat light guide 19 and perpendicularly with respect to a side face 190 of the flat light guide. The radiation exit face 25 runs perpendicularly with respect to the main extent plane of the connection carrier 15. In the arrangement shown, horizontal coupling of the light into a flat light guide 19 placed laterally next to the connection carrier occurs.

A side face 26 of the carrier 2, running perpendicularly with respect to the radiation exit face, may bear on the connection carrier. In this way “recumbent mounting” of the optoelectronic semiconductor component 1 on the connection carrier 15 is reliably achievable in a simplified way. In this case, a main extent plane of the semiconductor layer sequence 50 of the semiconductor bodies 5 runs perpendicularly or substantially perpendicularly with respect to the main extent plane of the connection carrier 15. Preferably, the thickness of the carrier 2, that is to say the extent perpendicularly with respect to the radiation exit face 25, is in this case so great that the optoelectronic semiconductor component 1 does not tilt during mounting.

By means of the side face 26 of the carrier 2, the optoelectronic semiconductor component 1 may furthermore also be coupled thermally to the connection carrier 15.

Furthermore preferably, the side face 26 is configured in such a way that no radiation, or at least only a negligible fraction of the radiation, is coupled out through the side face 26. This may, for example, be achieved by means of a sufficiently large refractive index difference between the carrier and the environment. As an alternative or in addition, the side face 26 of the carrier may be provided with a reflective layer, for example in the form of an encapsulation, in which the optoelectronic semiconductor component is embedded.

Such a reflective layer may also be employed in the exemplary embodiment of FIG. 3.

The fastening of the optoelectronic semiconductor component 1 on the connection carrier 15 may for example be carried out by means of adhesive bonding, soldering or sintering.

This patent application claims the priority of German Patent Application 10 2020 124 921.7, the disclosure content of which is incorporated here by reference.

The invention is not restricted by the description with the aid of the exemplary embodiments. Rather, the invention comprises any new feature and any combination of features, which in particular includes any combination of features in the patent claims, even if this feature or this combination is not itself explicitly specified in the patent claims or the exemplary embodiments.

List of References

| | |
|---|---|
| 1 | optoelectronic semiconductor component |
| 10 | optoelectronic arrangement |
| 15 | connection carrier |
| 17 | connecting means |
| 19 | flat light guide |
| 190 | side face of the flat light guide |
| 2 | carrier |
| 20 | carrier assembly |
| 21 | component region |
| 25 | radiation exit face |
| 26 | side face |
| 3 | filter layer |
| 31 | polarization filter |
| 311 | metal layer |
| 312 | protective layer |
| 35 | angle filter |
| 351 | first dielectric layer |
| 352 | second dielectric layer |
| 4 | radiation conversion layer |
| 41 | phosphor |
| 42 | matrix material |
| 5 | semiconductor body |
| 50 | semiconductor layer sequence |
| 51 | first semiconductor layer |
| 52 | second semiconductor layer |
| 53 | active region |
| 54 | connection face |
| 55 | center spacing |
| 56 | distance |
| 59 | row |
| 6 | contact layer |
| 65 | contact face |
| 7 | insulation layer |
| 75 | opening |
| 8 | temporary substrate |
| 9 | stamp |
| 95 | arrow |
| 99 | singulation line |

1. A method for producing a multiplicity of optoelectronic semiconductor components, having the steps:
a) providing a carrier assembly having a multiplicity of component regions;
b) forming a filter layer on the carrier assembly;
c) forming a radiation conversion layer on the filter layer;
d) arranging a multiplicity of semiconductor bodies on the radiation conversion layer, the semiconductor bodies respectively having a semiconductor layer sequence with an active region intended for the generation of radiation and being free of a substrate stabilizing the semiconductor body;
e) forming a contact layer in order to establish an electrical connection between the semiconductor bodies;
f) forming an insulation layer on the contact layer;
g) forming electrical contact pads, which respectively are electrically conductively connected to the contact layer; and
h) singulating the carrier assembly into the optoelectronic semiconductor components, the singulated optoelectronic semiconductor components respectively having a carrier as part of the carrier assembly, a multiplicity of semiconductor bodies and at least two electrical contact pads for the external electrical contacting;
wherein the filter layer has a polarization filter and/or an angle filter, the angle filter transmitting the radiation fractions which travel perpendicularly with respect to the radiation exit face and predominantly reflecting radiation fractions which impinge at an angle which is greater than a limit angle.

2. The method as claimed in claim 1,
wherein a plurality of semiconductor bodies are transferred simultaneously onto the carrier assembly in step d).

3. The method as claimed in claim 1,
wherein the semiconductor bodies are transferred from a temporary substrate in step d), a center spacing between neighboring semiconductor bodies remaining the same during the transfer.

4. The method as claimed in claim 3,
wherein the semiconductor bodies on the temporary substrate are tested and only semiconductor bodies functioning according to specification are transferred in step d).

5. The method as claimed in claim 3,
wherein the semiconductor bodies on the temporary substrate are free of a growth substrate for epitaxial deposition of the semiconductor layer sequence.

6. The method as claimed in claim 1,
wherein the radiation conversion layer is configured to be structured in such a way that a separate radiation conversion element of the radiation conversion layer is assigned to each component region and the radiation conversion layer is not divided in step h).

7. The method as claimed in claim 1, wherein the filter layer is divided in step h).

8. An optoelectronic semiconductor component, having
a carrier, which forms a radiation exit face of the optoelectronic semiconductor component;
a multiplicity of semiconductor bodies which are arranged on the carrier, the semiconductor bodies respectively having a semiconductor layer sequence with an active region intended for the generation of radiation and being free of a substrate stabilizing the semiconductor body;
a filter layer between the carrier and the semiconductor bodies, the filter layer having a polarization filter and/or an angle filter, the angle filter transmitting the radiation fractions which travel perpendicularly with respect to the radiation exit face and predominantly reflecting radiation fractions which impinge at an angle which is greater than a limit angle;
a radiation conversion layer between the carrier and the semiconductor bodies, the radiation conversion layer extending continuously over the semiconductor body;
a contact layer for establishing an electrical connection between the semiconductor bodies;
an insulation layer on a side of the contact layer facing away from the carrier; and
at least two electrical contact pads for the external electrical contacting, which are arranged on the insulation layer and are electrically conductively connected to the contact layer.

9. The optoelectronic semiconductor component as claimed in claim 8,
wherein the filter layer covers the carrier surface-wide and protrudes beyond the radiation conversion layer in a lateral direction.

10. The optoelectronic semiconductor component as claimed in claim 8,
wherein neighboring semiconductor bodies are arranged at a distance of between 1 µm inclusive and 10 µm inclusive from one another.

11. The optoelectronic semiconductor component as claimed in claim 8,
wherein the electrical contact pads together cover at least 60% of a base face of the optoelectronic semiconductor component.

12. The optoelectronic semiconductor component as claimed in claim 8,
wherein the semiconductor bodies are arranged in the form of a matrix, the semiconductor bodies being interconnected in series and/or parallel by means of the contact layer.

13. (canceled)

14. An optoelectronic arrangement having an optoelectronic semiconductor component as claimed in claim 8 and a connection carrier on which the optoelectronic semiconductor component is fastened.

15. The optoelectronic arrangement as claimed in claim 14,
wherein the radiation exit face extends parallel or substantially parallel to a main extent plane of the connection carrier.

16. The optoelectronic arrangement as claimed in claim 14,
wherein the radiation exit face runs perpendicularly or substantially perpendicularly with respect to a main extent plane of the connection carrier.

17. The optoelectronic arrangement as claimed in claim 16,
wherein a side face of the carrier, running obliquely or perpendicularly with respect to the radiation exit face, bears on the connection carrier.

18. The optoelectronic arrangement as claimed in claim 14,
wherein the optoelectronic arrangement is adapted to couple radiation coupled out from the radiation exit face during operation of the optoelectronic arrangement into a side face of a flat light guide.

19. An optoelectronic semiconductor component, having
a carrier, which forms a radiation exit face of the optoelectronic semiconductor component;
a multiplicity of semiconductor bodies which are arranged on the carrier, the semiconductor bodies respectively having a semiconductor layer sequence with an active region intended for the generation of radiation and being free of a substrate stabilizing the semiconductor body;
a filter layer between the carrier and the semiconductor bodies, the filter layer having a polarization filter and/or an angle filter, the angle filter transmitting the radiation fractions which travel perpendicularly with respect to the radiation exit face and predominantly reflecting radiation fractions which impinge at an angle which is greater than a limit angle;
a radiation conversion layer between the carrier and the semiconductor bodies, the radiation conversion layer extending continuously over the semiconductor body;
a contact layer for establishing an electrical connection between the semiconductor bodies;
an insulation layer on a side of the contact layer facing away from the carrier; and
at least two electrical contact pads for the external electrical contacting, which are arranged on the insulation layer and are electrically conductively connected to the contact layer,
wherein the optoelectronic semiconductor component is produced by a method as claimed in claim 1.
